(19) United States
(12) Patent Application Publication
(10) Pub. No.: US 2026/0150438 A1
(43) Pub. Date: May 28, 2026

(54) LIGHT EMITTING DIODE AND DISPLAY DEVICE INCLUDING THE SAME

(71) Applicant: LG Display Co., Ltd., Seoul (KR)

(72) Inventors: Jinhyeon YUN, Paju-si (KR); Yuseop SHIN, Bucheon-si (KR); Kiyong HONG, Paju-si (KR); Kiyoung SONG, Paju-si (KR); Jihyun KOO, Seoul (KR); Byungyeon CHOI, Goyang-si (KR)

(73) Assignee: LG Display Co., Ltd., Seoul (KR)

(21) Appl. No.: 19/192,089

(22) Filed: Apr. 28, 2025

(30) Foreign Application Priority Data
Nov. 28, 2024 (KR) 10-2024-0174018

(51) Int. Cl. H10H 20/832; H10H 20/84; H10H 29/32; H10H 29/41; H10H 29/49

(52) U.S. Cl. CPC H10H 20/832; H10H 20/84; H10H 29/32; H10H 29/41; H10H 29/49

(57) ABSTRACT

A light emitting diode and a display device including such light emitting diodes are discussed. The light emitting diode can include a first semiconductor layer, an emission layer disposed on the first semiconductor layer, a second semiconductor layer disposed on the emission layer, a magnetic metal disposed below the first semiconductor layer, and an insulating layer disposed to enclose a side surface of the magnetic metal. Therefore, such light emitting diodes which emit different color lights can be simultaneously assembled.

### CROSS-REFERENCE TO RELATED APPLICATIONS

This application claims priority to Korean Patent Application No. 10-2024-0174018 filed on Nov. 28, 2024, in the Korean Intellectual Property Office, the entire disclosure of which is hereby expressly incorporated by reference into the present application.

### BACKGROUND

### Field

The present disclosure relates to a display device, and more particularly to a display device which is capable of being simultaneously assembled.

### Description of the Related Art

Among display devices which are used for a monitor of a computer, a television, or a cellular phone, there are an organic light emitting display device (OLED) which is a self-emitting device and a liquid crystal display device (LCD) which requires a separate light source.

An applicable range of the display device can be diversified to personal digital assistants as well as monitors of computers and televisions and a display device with a large display area and a reduced volume and weight is being studied.

Further, recently, a display device including a light emitting diode (LED) is attracting attention as a next generation display device. Since the LED is formed of an inorganic material, rather than an organic material, reliability is excellent so that a lifespan thereof is longer than that of the liquid crystal display device or the organic light emitting display device. Further, the LED has a fast lighting speed, excellent luminous efficiency, and a strong impact resistance so that a stability is excellent and an image having a high luminance can be displayed.

### SUMMARY OF THE DISCLOSURE

An object to be achieved by the present disclosure is to provide light emitting diodes which emit different color lights but are simultaneously assembled, and to provide a display device including the same.

An object to be achieved by the present disclosure is to provide light emitting diodes that are formed to have the same size to be easily control the size and a defect, and to provide a display device including the same.

An object to be achieved by the present disclosure is to provide a display device whose production efficiency is improved by reducing a number of times of performing an assembling process of a light emitting diode.

Objects of the present disclosure are not limited to the above-mentioned objects, and other objects, which are not mentioned above, can be clearly understood by those skilled in the art from the following descriptions.

According to aspects of the present disclosure, a light emitting diode includes a first semiconductor layer, an emission layer disposed on the first semiconductor layer, a second semiconductor layer disposed on the emission layer, a magnetic metal disposed below the first semiconductor layer, and an insulating layer disposed to enclose a side surface of the magnetic metal.

According to aspects of the present disclosure, a substrate for assembling a light emitting diode includes a base substrate, a plurality of assembly electrodes disposed on the base substrate, and an organic layer which is disposed on the base substrate and includes a plurality of openings which exposes the plurality of assembly electrodes and the plurality of assembly electrodes includes a plurality of first assembly electrodes, a plurality of second assembly electrodes, and a plurality of third assembly electrodes having different planar shapes.

According to aspects of the present disclosure, a display device includes a substrate in which a plurality of sub pixels is defined, a power line disposed on the substrate, a plurality of transistors disposed in each of the plurality of sub pixels on the substrate, and a plurality of light emitting diodes which is disposed in each of the plurality of sub pixels on the power line and the plurality of transistors. The plurality of light emitting diodes includes a first light emitting diode, a second light emitting diode, and a third light emitting diode which emit different color lights. The plurality of light emitting diodes includes a first semiconductor layer, an emission layer disposed on the first semiconductor layer, a second semiconductor layer disposed on the emission layer, a magnetic metal disposed below the first semiconductor layer, and an insulating layer disposed so as to enclose a side surface of the magnetic metal. A magnetic metal of the first light emitting diode, a magnetic metal of the second light emitting diode, and a magnetic metal of the third light emitting diode have different planar shapes. Therefore, the plurality of light emitting diodes which emits different color lights can be simultaneously assembled.

Other detailed matters of the example embodiments are included in the detailed description and the drawings.

According to the example embodiment of the present disclosure, a plurality of light emitting diodes which emits different color lights is formed to have different shapes of magnetic metal to divide the plurality of light emitting diodes which emits different color lights during self-assembling.

According to the example embodiment of the present disclosure, a plurality of light emitting diodes which emits different color lights can be simultaneously assembled.

According to the example embodiment of the present disclosure, the light emitting diodes are formed to have the same size so that there is no need to manage the size exclusiveness of the light emitting diode, thereby easily managing a size and a defect of the light emitting diode.

According to the example embodiments of the present disclosure, the light emitting diodes which emit different color lights are simultaneously assembled to simplify the assembly process, thereby implementing process optimization.

The effects according to the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a cross-sectional view of a light emitting diode according to one or more example embodiments of the present disclosure;

FIGS. 2A to 2C are rear views of a light emitting diode according to an example embodiment of the present disclosure;

FIG. 3 is a cross-sectional view of a light emitting diode according to another example embodiment of the present disclosure;

FIG. 4 is a cross-sectional view of a light emitting diode according to still another example embodiment of the present disclosure;

FIG. 5 is a cross-sectional view of a light emitting diode according to still another example embodiment of the present disclosure;

FIG. 6A is a view for explaining a manufacturing method of a display device according to an example embodiment of the present disclosure;

FIG. 6B is a cross-sectional view of an assembling substrate according to an example embodiment of the present disclosure;

FIG. 7 is a schematic diagram of a display device according to an example embodiment of the present disclosure;

FIG. 8 is a cross-sectional view of a display device according to an example embodiment of the present disclosure;

FIG. 9 is a cross-sectional view of a display device according to another example embodiment of the present disclosure;

FIG. 10 is a cross-sectional view of a display device according to still another example embodiment of the present disclosure; and

FIG. 11 is a cross-sectional view of a display device according to still another example embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated. Further, the term “can” fully encompasses all the meanings and coverages of the term “may” and vice versa.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components and may not define order or sequence. Therefore, a first component to be mentioned below can be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other

Hereinafter, a light emitting diode and a display device including the same according to example embodiments of the present disclosure will be described in detail with reference to accompanying drawings. Here, all the components of each light emitting diode and each display device according to all embodiments of the present disclosure are operatively coupled and configured.

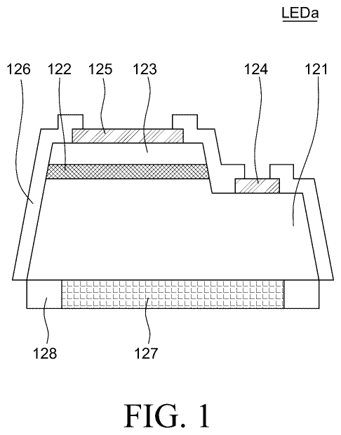

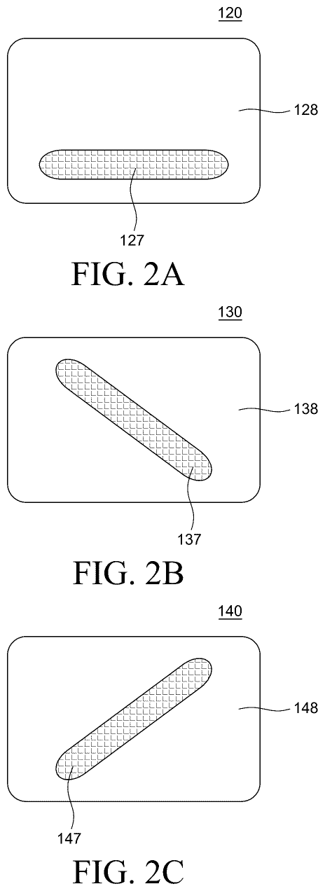

FIG. 1 is a cross-sectional view of a light emitting diode according to one or more example embodiments of the present disclosure. FIGS. 2A to 2C are rear views of a light emitting diode according to an example embodiment of the present disclosure. Particularly, FIG. 1 is a cross-sectional view of a first light emitting diode 120, among light emitting diodes LEDa, FIG. 2A is a rear view of a first light emitting diode 120, FIG. 2B is a rear view of a second light emitting diode 130, and FIG. 2C is a rear view of a third light emitting diode 140.

Referring to FIGS. 1 to 2C, the light emitting diodes LEDa according to the example embodiment of the present disclosure can include a first light emitting diode 120, a second light emitting diode 130, and a third light emitting diode 140 which emit different color lights. For example, the first light emitting diode 120 can be a red light emitting diode, the second light emitting diode 130 can be a green light emitting diode, and the third light emitting diode 140 can be a blue light emitting diode.

Referring to FIGS. 1 and 2A, the light emitting diodes LEDa according to the example embodiment of the present disclosure include a first semiconductor layer 121, an emission layer 122, a second semiconductor layer 123, a first electrode 124, a second electrode 125, a passivation film 126, a magnetic metal 127, and an insulating layer 128.

The first semiconductor layer 121 and the second semiconductor layer 123 can be layers formed by doping n-type and p-type impurities into a specific material. For example, the first semiconductor layer 121 and the second semiconductor layer 123 can be layers doped with n type and p type impurities into a material such as gallium nitride (GaN), indium aluminum phosphide (InAlP), or gallium arsenide (GaAs). The p-type impurity can be magnesium (Mg), zinc (Zn), and beryllium (Be), and the n-type impurity can be silicon (Si), germanium, and tin (Sn), but is not limited thereto.

The emission layer 122 can be disposed between the first semiconductor layer 121 and the second semiconductor layer 123. The emission layer 122 is supplied with holes and electrons from the first semiconductor layer 121 and the second semiconductor layer 123 to emit light.

The emission layer 122 can be formed by a single layer or a multi-quantum well (MQW) structure, and for example, can be formed of indium gallium nitride (InGaN) or gallium nitride (GaN), but is not limited thereto.

The first electrode 124 can be disposed on the first semiconductor layer 121. The first semiconductor layer 121 is a semiconductor layer doped with an n-type impurity and the first electrode 124 can be a cathode. The first electrode 124 can be disposed on a top surface of the first semiconductor layer 121 which is exposed from the emission layer 122 and the second semiconductor layer 123. The first electrode 124 can be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The second electrode 125 can be disposed on the second semiconductor layer 123. The second electrode 125 can be disposed on the top surface of the second semiconductor layer 123. At this time, the second semiconductor layer 123 is disposed on the first semiconductor layer 121 so that the second electrode 125 disposed on the top surface of the second semiconductor layer 123 can be disposed to be higher than the first electrode 124 disposed on the top surface of the first semiconductor layer 121. The second semiconductor layer 123 is a semiconductor layer doped with a p-type impurity and the second electrode 125 can be an anode. The second electrode 125 can be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The passivation film 126 which encloses the first semiconductor layer 121, the emission layer 122, the second semiconductor layer 123, the first electrode 124, and the second electrode 125 can be disposed. The passivation film 126 can be formed of an insulating material to protect the first semiconductor layer 121, the emission layer 122, and the second semiconductor layer 123. For example, the passivation film 126 can be configured by transparent epoxy, alumina (Al2O3), silicon oxide (SiOx), or silicon nitride (SiNx), but is not limited thereto. A contact hole which exposes the first electrode 124 and the second electrode 125 can be formed in the passivation film 126.

The magnetic metal 127 can be disposed below the first semiconductor layer 121. The magnetic metal 127 can be formed of a magnetic material so that the light emitting diode LEDa can move toward an assembly electrode of an assembling substrate by a magnetic field. At this time, if a magnetic force between the assembly electrode of the assembling substrate and the light emitting diode LEDa is too strong, the light emitting diode LEDa is not easily separated from the assembling substrate during a process transferring the light emitting diode LEDa from the assembling substrate to the display panel. Therefore, the light emitting diode LEDa may not be properly transferred from the assembling substrate to the display panel. Therefore, the magnetic metal 127 can include a paramagnetic material rather than a ferromagnetic material so that the light emitting element LEDa can be easily separated from the assembling substrate during the transfer process while having a magnetic force with an assembly electrode. For example, the magnetic metal 127 can be formed of a paramagnetic material, such as aluminum (Al) or manganese (Mn), but is not limited thereto.

The magnetic metal 127 is disposed below the first semiconductor layer 121 to be in contact with the first semiconductor layer 121. For example, an area of the magnetic metal 127 can be smaller than an area of the first semiconductor layer 121. Therefore, the magnetic metal 127 can expose at least a part of a bottom surface of the first semiconductor layer 121, but is not limited thereto.

The insulating layer 128 can be disposed below the first semiconductor layer 121. The insulating layer 128 is disposed so as to enclose a side surface of the magnetic metal 127 to planarize a step between the magnetic metal 127 and the first semiconductor layer 121 and protect the magnetic metal 127, concurrently. Therefore, the insulating layer 128 can be disposed so as to cover the first semiconductor layer 121 which is exposed by the magnetic metal 127. Accordingly, an end of the insulating layer 128 can be disposed on the same plane as an end of the first semiconductor layer 121, but is not limited thereto and extends to cover the lower portion of the passivation film 126 and can be disposed on the same plane as the end of the passivation film 126.

Therefore, the insulating layer 128 can be disposed to be spaced apart from the passivation film 126. For example, the insulating layer 128 can be separately formed from the passivation film 126 to be spaced apart from the passivation film 126, but is not limited thereto.

For example, the insulating layer 128 can be formed of an inorganic insulating material, such as silicon oxide (SiOx) or silicon nitride (SiNx), but is not limited thereto and can be formed of an organic material.

In the meantime, the first light emitting diode 120, among the light emitting diodes LEDa, has been described with reference to FIG. 1. However, the remaining components of the second light emitting diode 130 and the third light emitting diode 140 have the same shape and configuration as those of the first light emitting diode 120, except for a color of light emitted by the emission layer, a magnetic metal, and an insulating layer.

In the light emitting diodes LEDa according to the example embodiment of the present disclosure, magnetic metals 128, 138, and 148 of the light emitting diodes LEDa disposed in different sub pixels are configured to have different shapes to distinguish the plurality of light emitting diodes LEDa. Therefore, when the light emitting diodes LEDa are self-assembled, the magnetic metals 128, 138, and 148 of the plurality of light emitting diodes LEDa are formed to have different shapes to be self-assembled in a position corresponding to each of the plurality of sub pixels.

Specifically, referring to FIGS. 2A to 2C, a magnetic metal 127 of the first light emitting diode 120, a magnetic metal 137 of the second light emitting diode 130, and a magnetic metal 147 of the third light emitting diode 140 are formed to have the same shape, but placement positions or directions in the light emitting diodes LEDa can be different. For example, the magnetic metal 127 of the first light emitting diode 120 can be disposed to be biased to an edge of the first light emitting diode 120. The center of the magnetic metal 137 of the second light emitting diode 130 is disposed so as to correspond to the center of the second light emitting diode 130 to be diagonally disposed from an upper left to a lower right. The center of the magnetic metal 147 of the third light emitting diode 140 is disposed so as to correspond to the center of the third light emitting diode 140 to be diagonally disposed from an upper right to a lower left. However, FIGS. 2A to 2C are just illustrative, but are not limited thereto.

For example, unlike FIGS. 2A to 2C, the magnetic metal 127 of the first light emitting diode 120, the magnetic metal 137 of the second light emitting diode 130, and the magnetic metal 147 of the third light emitting diode 140 are configured to have different sizes and shapes to distinguish the first light emitting diode 120, the second light emitting diode 130, and the third light emitting diode 140.

As one of methods for manufacturing a display device, a self-assembling method can be used. For example, the plurality of light emitting diodes is assembled on the assembling substrate so as to correspond to a sub pixel and then can be transferred to the display panel as they are assembled on the assembling substrate. For example, in order to simultaneously assemble light emitting diodes which emit different color lights in a position corresponding to each sub pixel, the light emitting diodes have different sizes and shapes to be distinguished. However, when the above-described method is used, the exclusiveness of the size and the shape of each light emitting diode needs to be maintained and it is difficult to maintain a uniformity of sizes between light emitting diodes which emit the same color light.

Alternatively, a method of separately assembling the light emitting diodes which emit different color lights can be used. For example, only light emitting diodes which emit one same color light are filled in one tray to perform the self-assembly. However, when the self-assembly is performed by filling only light emitting diodes which emit one same color light in one tray, the light emitting diodes are individually assembled so that there is a problem in that the number of times of performing an assembling process is increased to increase a process time and a process cost.

Therefore, the light emitting diodes LEDa according to the example embodiment of the present disclosure are formed to have the same planar shape and size regardless of a color of emitted light. However, the magnetic metals 127, 137, and 147 of the light emitting diodes LEDa are configured to have different shapes to distinguish the light emitting diodes LEDa during the self-assembly. For example, the first light emitting diode 120, the second light emitting diode 130, and the third light emitting diode 140 which emit different color lights have the same size and shape. However, the magnetic metal 127 of the first light emitting diode 120, the magnetic metal 137 of the second light emitting diode 130, and the magnetic metal 147 of the third light emitting diode 140 have different planar shapes. Therefore, the first light emitting diode 120, the second light emitting diode 130, and the third light emitting diode 140 can be selectively assembled in positions of corresponding assembly grooves. For example, the assembly position of each light emitting diode LEDa can be controlled by giving the exclusiveness to the planar shapes of the magnetic metals 127, 137, and 147 of the light emitting diodes LEDa according to the example embodiment of the present disclosure. Accordingly, even though light emitting diodes LEDa having the same size are mixed in one tray as the light emitting diode LEDa according to the example embodiment of the present disclosure, the plurality of light emitting diodes LEDa which emits different color lights can be selectively assembled to be simultaneously assembled. Therefore, as compared with an example that the self-assembly is performed by filling only the light emitting diodes which emit one same color light in one tray, the number of times of performing an assembling process can be reduced. As such, the production efficiency can be improved and a manufacturing cost can be saved. Thus, the manufacturing process is simplified to implement process optimization.

Further, regardless of the color of emitted light, all the light emitting diodes LEDa according to the example embodiment of the present disclosure have the same size so that there is no need to provide a separate mask for manufacturing the light emitting diodes LEDa depending on the color of emitted light. Therefore, the manufacturing cost can be saved. Further, there is no need to to manage the size exclusiveness between light emitting diodes LEDa which emit different color lights and further the size uniformity between the light emitting diodes LEDa can be relatively easily managed, thereby improving the production efficiency of the light emitting diode LEDa.

Furthermore, the light emitting diodes LEDa according to the example embodiment of the present disclosure can include insulating layers 128, 138, and 148 which are disposed so as to enclose the side surfaces of the magnetic metals 127, 137 and 147. The insulating layers 128, 138, and 148 are disposed so as to enclose the first semiconductor layer 121 exposed by the magnetic metals 127, 137, and 147 to alleviate the steps between the magnetic metals 127, 137, and 147 and the first semiconductor layer 121 and protect the magnetic metals 127, 137, and 147, concurrently. Therefore, the breakage defect of the light emitting diodes LEDa which can occur during the assembling process can be minimized or reduced.

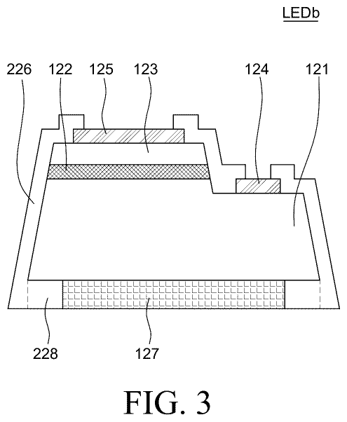

FIG. 3 is a cross-sectional view of a light emitting diode according to another example embodiment of the present disclosure. Components of a light emitting diode LEDb of FIG. 3 are substantially the same as the light emitting diode LEDa of FIGS. 1 to 2C except for a passivation film 226 and an insulating layer 228, so that a redundant description will be omitted or briefly provided.

Referring to FIG. 3, a passivation film 226 can be integrally formed with an insulating layer 228. For example, the passivation film 226 and the insulating layer 228 can be simultaneously formed by one process to be formed of the same material. Therefore, the passivation film 226 can be disposed so as to cover not only the first semiconductor layer 121, the emission layer 122, the second semiconductor layer 123, the first electrode 124, and the second electrode 125, but also a side surface of the insulating layer 228.

For example, the passivation film 226 and the insulating layer 228 can be formed of the same insulating material. Therefore, the first semiconductor layer 121, the emission layer 122, the second semiconductor layer 123, and the magnetic metal 127 can be protected and the step between the magnetic metal 127 and the first semiconductor layer 121 can be planarized, concurrently.

For example, the passivation film 226 and the insulating layer 228 can be configured by transparent epoxy, alumina (Al2O3), silicon oxide (SiOx), or silicon nitride (SiNx), but is not limited thereto.

The light emitting diodes LEDb according to another example embodiment of the present disclosure are formed to have the same planar shape and size regardless of a color of emitted light. However, the magnetic metals 127, 137, and 147 of the light emitting diodes LEDb are configured to have different planar shapes to distinguish the light emitting diodes LEDb during the self-assembly. Therefore, a first light emitting diode 220, a second light emitting diode 230, and a third light emitting diode 240 which emit different color lights can be selectively assembled in positions of corresponding assembly grooves. For example, the assembly position of each light emitting diode LEDb can be controlled by giving the exclusiveness to the planar shapes of the magnetic metals 127, 137, and 147 of the light emitting diodes LEDb according to another example embodiment of the present disclosure. Accordingly, even though light emitting diodes LEDb having the same size are mixed in one tray as the light emitting diode LEDb according to another example embodiment of the present disclosure, the plurality of light emitting diodes LEDb which emits different color lights can be selectively assembled to be simultaneously assembled. As such, as compared with an example that the self-assembly is performed by filling only the light emitting diodes which emit one same color light in one tray, the number of times of performing an assembling process can be reduced. Thus, the production efficiency can be improved and a manufacturing cost can be saved.

Further, regardless of the color of emitted light, all the light emitting diodes LEDb according to another example embodiment of the present disclosure have the same size so that there is no need to provide a separate mask for manufacturing the light emitting diodes LEDb depending on the color of emitted light. Therefore, the manufacturing cost can be saved. Furthermore, there is no need to manage the size exclusiveness between light emitting diodes LEDb which emit different color lights and further the size uniformity between the light emitting diodes LEDb can be relatively easily managed to improve the production efficiency of the light emitting diode LEDb.

In addition, the light emitting diodes LEDb according to another example embodiment of the present disclosure can include the insulating layer 228 which is disposed so as to enclose the side surface of the magnetic metal 127. The insulating layer 228 can be disposed so as to cover the first semiconductor layer 121 exposed by the magnetic metals 127, 137, and 147 to alleviate the steps between the magnetic metals 127, 137, and 147 and the first semiconductor layer 121 and protect the magnetic metals 127, 137, and 147. Therefore, the breakage defect of the light emitting diodes LEDb which can occur during the assembling process can be minimized or reduced.

Specifically, in the light emitting diode LEDb according to another example embodiment of the present disclosure, the passivation film 226 can be integrally formed with the insulating layer 228. For example, the passivation film 226 and the insulating layer 228 can be simultaneously formed by one process. Therefore, a process for separately forming the passivation film 226 and the insulating layer 228 can be omitted. Therefore, the production efficiency can be improved and a manufacturing cost can be saved. Therefore, the manufacturing process is simplified to implement process optimization.

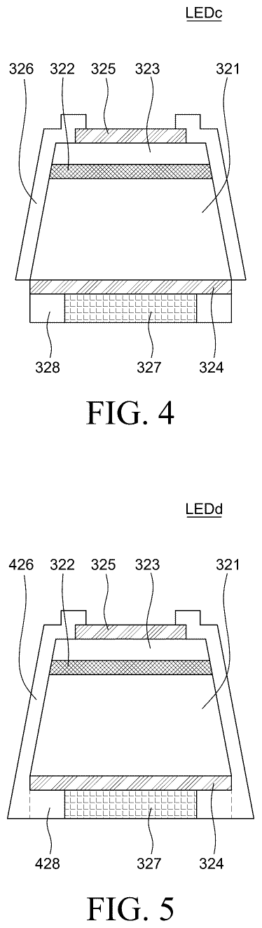

FIG. 4 is a cross-sectional view of a light emitting diode according to still another example embodiment of the present disclosure. A light emitting diode LEDc of FIG. 4 can have a vertical structure, unlike the light emitting diode LEDa of FIGS. 1 to 2C and the light emitting diode LEDb of FIG. 3.

Referring to FIG. 4, the light emitting diodes LEDc according to still another example embodiment of the present disclosure include a first semiconductor layer 321, an emission layer 322, a second semiconductor layer 323, a first electrode 324, a second electrode 325, a passivation film 326, a magnetic metal 327, and an insulating layer 328.

The first semiconductor layer 321 and the second semiconductor layer 323 can be layers formed by doping n-type and p-type impurities into a specific material. For example, the first semiconductor layer 321 and the second semiconductor layer 323 can be layers doped with n type and p type impurities into a material such as gallium nitride (GaN), indium aluminum phosphide (InAlP), or gallium arsenide (GaAs). The p-type impurity can be magnesium (Mg), zinc (Zn), and beryllium (Be), and the n-type impurity can be silicon (Si), germanium, and tin (Sn), but is not limited thereto.

The emission layer 322 can be disposed between the first semiconductor layer 321 and the second semiconductor layer 323. The emission layer 322 is supplied with holes and electrons from the first semiconductor layer 321 and the second semiconductor layer 323 to emit light.

The emission layer 322 can be formed by a single layer or a multi-quantum well (MQW) structure, and for example, can be formed of indium gallium nitride (InGaN) or gallium nitride (GaN), but is not limited thereto.

The first electrode 324 can be disposed below the first semiconductor layer 321. The first semiconductor layer 321 is a semiconductor layer doped with an n-type impurity and the first electrode 324 can be a cathode. The first electrode 324 can be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The second electrode 325 can be disposed on the second semiconductor layer 323. The second electrode 325 can be disposed on the top surface of the second semiconductor layer 323. At this time, the second semiconductor layer 323 is disposed on the first semiconductor layer 321 so that the second electrode 325 disposed on the top surface of the second semiconductor layer 323 can be disposed to be higher than the first electrode 324 disposed on the top surface of the first semiconductor layer 321. The second semiconductor layer 323 is a semiconductor layer doped with a p-type impurity and the second electrode 325 can be an anode. The second electrode 325 can be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The passivation film 326 which encloses the first semiconductor layer 321, the emission layer 322, the second semiconductor layer 323, and the second electrode 325 can be disposed. The passivation film 326 can be formed of an insulating material to protect the first semiconductor layer 321, the emission layer 322, and the second semiconductor layer 323. For example, the passivation film 326 can be configured by transparent epoxy, alumina (Al2O3), silicon oxide (SiOx), or silicon nitride (SiNx), but is not limited thereto. A contact hole which exposes the second electrode 325 can be formed in the passivation film 326.

The magnetic metal 327 can be disposed below the first electrode 324. The magnetic metal 327 can be formed of a metallic magnetic material so that the light emitting diode LEDc can move to an assembly electrode of an assembling substrate by a magnetic field. For example, the magnetic metal 327 can be formed of a paramagnetic material, such as aluminum (Al) or manganese (Mn), but is not limited thereto.

The magnetic metal 327 can be disposed below the first electrode 324 to electrically contact with the first electrode 324. For example, an area of the magnetic metal 327 can be smaller than an area of the first electrode 324. Therefore, the magnetic metal 327 can expose at least a part of a bottom surface of the first electrode 324, but is not limited thereto.

The insulating layer 328 can be disposed below the first electrode 324. The insulating layer 328 is disposed so as to enclose a side surface of the magnetic metal 327 to planarize a step between the magnetic metal 327 and the first electrode 324 and protect the magnetic metal 327, concurrently. Therefore, the insulating layer 328 can be disposed so as to cover the first electrode 324 which is exposed by the magnetic metal 327. Accordingly, an end of the insulating layer 328 can be disposed on the same plane as an end of the first electrode 324, but is not limited thereto.

Therefore, the insulating layer 328 can be disposed to be spaced apart from the passivation film 326. For example, the insulating layer 328 can be separately formed from the passivation film 326 to be spaced apart from the passivation film 326, but is not limited thereto.

For example, the insulating layer 328 can be formed of an inorganic insulating material, such as silicon oxide (SiOx) or silicon nitride (SiNx), but is not limited thereto and can be formed of an organic material.

The light emitting diodes LEDc according to still another example embodiment of the present disclosure are formed to have the same planar shape and size regardless of a color of emitted light. However, the magnetic metal 327 of each light emitting diode LEDc is configured to have a different planar shape to distinguish the light emitting diodes LEDc during the self-assembly. Therefore, a first light emitting diode, a second light emitting diode, and a third light emitting diode which emit different color lights can be selectively assembled in positions of corresponding assembly grooves. For example, the assembly position of each light emitting diode LEDc can be controlled by giving the exclusiveness to the planar shapes of the magnetic metal 327 of light emitting diode LEDc according to still another example embodiment of the present disclosure. Accordingly, even though light emitting diodes LEDc having the same size are mixed in one tray as the light emitting diode LEDc according to still another example embodiment of the present disclosure, the plurality of light emitting diodes LEDc which emits different color lights can be selectively assembled to be simultaneously assembled. As such, as compared with an example that the self-assembly is performed by filling only the light emitting diodes which emit one same color light in one tray, the number of times of performing an assembling process can be reduced. Thus, the production efficiency can be improved and a manufacturing cost can be saved.

Further, regardless of the color of emitted light, all the light emitting diodes LEDc according to another example embodiment of the present disclosure have the same size so that there is no need to provide a separate mask for manufacturing the light emitting diodes LEDc depending on the color of emitted light. Therefore, the manufacturing cost can be saved. Further, there is no need to manage the size exclusiveness between light emitting diodes LEDc which emits different color lights and further the size uniformity between the light emitting diodes LEDc can be relatively easily managed to improve the production efficiency of the light emitting diode LEDc.

Furthermore, the light emitting diode LEDc according to still another example embodiment of the present disclosure can include the insulating layer 328 disposed to enclose the side surface of the magnetic metal 327. The insulating layer 328 is disposed so as to cover the first electrode 324 exposed by the magnetic metal 327 to alleviate the step between the magnetic metal 327 and the first electrode 324 and protect the magnetic metal 327. Therefore, the breakage defect of the light emitting diode LEDc which can occur during the assembling process can be minimized or reduced.

FIG. 5 is a cross-sectional view of a light emitting diode according to still another example embodiment of the present disclosure. Components of a light emitting diode LEDd of FIG. 5 are substantially the same as the light emitting diode LEDc of FIG. 4 except for a passivation film 426 and an insulating layer 428, so that a redundant description will be omitted or briefly provided.

Referring to FIG. 5, the passivation film 426 can be integrally formed with the insulating layer 428. For example, the passivation film 426 and the insulating layer 428 can be simultaneously formed by one process to be formed of the same material. Therefore, the passivation film 426 can be disposed so as to cover not only the first semiconductor layer 321, the emission layer 322, the second semiconductor layer 323, the first electrode 324, and the second electrode 325, but also a side surface of the insulating layer 428.

For example, the passivation film 426 and the insulating layer 428 can be formed of the same insulating material so that the first semiconductor layer 321, the emission layer 322, the second semiconductor layer 323, and the magnetic metal 327 can be protected and the step between the magnetic metal 327 and the first semiconductor layer 321 can be planarized, concurrently.

For example, the passivation film 426 and the insulating layer 428 can be configured by transparent epoxy, alumina (Al2O3), silicon oxide (SiOx), or silicon nitride (SiNx), but is not limited thereto.

The light emitting diodes LEDd according to still another example embodiment of the present disclosure are formed to have the same planar shape and size regardless of a color of emitted light. However, the magnetic metal 327 of each light emitting diode LEDd is configured to have a different planar shape to distinguish the light emitting diodes LEDd during the self-assembly. Therefore, a first light emitting diode, a second light emitting diode, and a third light emitting diode which emit different color lights can be selectively assembled in positions of corresponding assembly grooves. For example, the assembly position of each light emitting diode LEDd can be controlled by giving the exclusiveness to the planar shapes of the magnetic metal 327 of light emitting diode LEDd according to still another example embodiment of the present disclosure. Accordingly, even though light emitting diodes LEDd having the same size are mixed in one tray as the light emitting diode LEDd according to still another example embodiment of the present disclosure, the plurality of light emitting diodes LEDd which emits different color lights can be selectively assembled to be simultaneously assembled. As such, as compared with an example that the self-assembly is performed by filling only the light emitting diodes which emit one same color light in one tray, the number of times of performing an assembling process can be reduced. Thus, the production efficiency can be improved and a manufacturing cost can be saved.

Further, regardless of the color of emitted light, all the light emitting diodes LEDd according to another example embodiment of the present disclosure have the same size so that there is no need to provide a separate mask for manufacturing the light emitting diodes LEDd depending on the color of emitted light. Therefore, the manufacturing cost can be saved. Further, there is no need to manage the size exclusiveness between light emitting diodes LEDd which emit different color lights and further the size uniformity between the light emitting diodes LEDd can be relatively easily managed to improve the production efficiency of the light emitting diode LEDd.

Furthermore, the light emitting diode LEDd according to still another example embodiment of the present disclosure can include the insulating layer 428 disposed to enclose the side surface of the magnetic metal 327. The insulating layer 428 is disposed so as to cover the first electrode 324 exposed by the magnetic metal 327 to alleviate the step between the magnetic metal 327 and the first electrode 324 and protect the magnetic metal 327. Therefore, the breakage defect of the light emitting diode LEDd which can occur during the assembling process can be minimized or reduced.

Specifically, in the light emitting diode LEDd according to another example embodiment of the present disclosure, the passivation film 426 can be integrally formed with the insulating layer 428. For example, the passivation film 426 and the insulating layer 428 can be simultaneously formed by one process. Therefore, a process for separately forming the passivation film 426 and the insulating layer 428 can be omitted. Therefore, the production efficiency can be improved and a manufacturing cost can be saved.

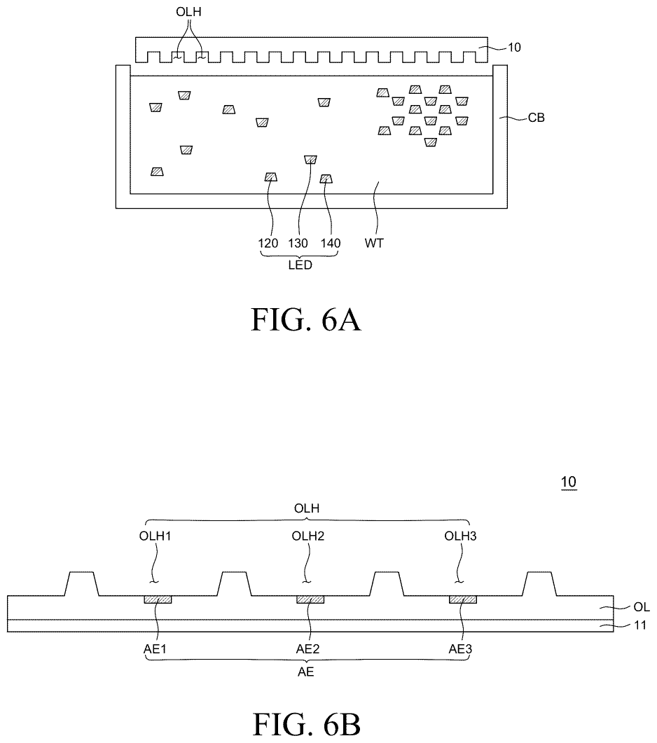

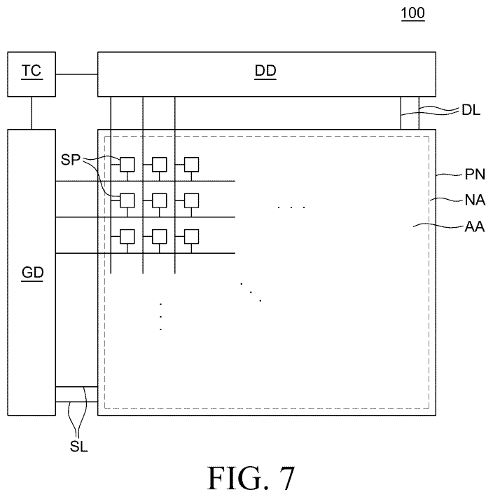

FIG. 6A is a view for explaining a manufacturing method of a display device according to an example embodiment of the present disclosure. FIG. 6B is a cross-sectional view of an assembling substrate according to an example embodiment of the present disclosure.

Referring to FIGS. 6A and 6B, the assembling substrate 10 includes a base substrate 11, a plurality of assembly electrodes AE, and an organic layer OL.

First, the organic layer OL including a plurality of openings OLH can be disposed on the base substrate 11. A thickness of the organic layer OL which can be formed by one process is limited. If the thickness of the organic layer OL is equal to or smaller than a predetermined level, the light emitting diode LED which is self-assembled in the opening OLH of the organic layer OL may not be properly seated in the opening OLH. In contrast, when the thickness of the organic layer OL can be excessively thick, it can be difficult to attach the light emitting diode which is self-assembled in the opening OLH of the organic layer OL to the donor. Therefore, the thickness of the organic layer OL can be adjusted by forming a plurality of organic layers OL. The organic layer OL can at least have a thickness smaller than a height of the light emitting diode. Even though in FIGS. 6A and 6B, it is illustrated that the organic layer OL is configured as a single layer, a plurality of organic layers OL can be formed, but is not limited thereto.

The organic layer OL can include a plurality of openings OLH. Each of the plurality of openings OLH which is formed by opening a part of the organic layer OL is an area in which the plurality of light emitting diodes LED is self-assembled. The plurality of openings OLH is disposed so as to overlap the assembly electrode AE to expose the assembly electrode AE.

The plurality of openings OLH can include a plurality of first openings OLH1, a plurality of second openings OLH2, and a plurality of third openings OLH3.

For example, each of the plurality of first openings OLH1, the plurality of second openings OLH2, and the plurality of third openings OLH3 can be disposed so as to correspond to a plurality of first sub pixels, a plurality of second sub pixels, and a plurality of third sub pixels. Accordingly, the light emitting diode which is self-assembled in the plurality of openings OLH can be transferred to the plurality of sub pixels as it is.

For example, in the first opening OLH1, the first light emitting diode 120 is assembled, in the second opening OLH2, the second light emitting diode 130 is assembled, and in the third opening OLH3, the third light emitting diode 140 is assembled.

For example, the first light emitting diode 120, the second light emitting diode 130, and the third light emitting diode 140 can have the same size and the same planar shape so that the first opening OLH1, the second opening OLH2, and the third opening OHL3 can have the same width and shape.

A plurality of assembly electrodes AE can be disposed on the base substrate 11. Specifically, the plurality of assembly electrodes AE can be disposed on the organic layer OL to be exposed by the plurality of openings OLH. The plurality of assembly electrodes AE can include a magnetic material. Therefore, the light emitting diodes LED which are sunken on the bottom of the chamber CB or float can move toward the assembling substrate 10 by a magnetic force generated between the assembly electrode AE and the light emitting diodes LED.

At this time, when the magnetic force between the assembly electrode AE and the light emitting diode LED is too strong, the light emitting diode LED is not easily separated from the assembling substrate 10 during the process of transferring the light emitting diode LED from the assembling substrate 10 to the display panel PN. Therefore, the light emitting diode LED can be not properly transferred from the assembling substrate 10 to the display panel PN. Therefore, the assembly electrode AE can include a paramagnetic material rather than a ferromagnetic material so that the light emitting element LED can be easily separated from the assembling substrate 11 during the transfer process while having a magnetic force with the magnetic metal 127. For example, the magnetic metal 127 can be formed of a paramagnetic material, such as aluminum (Al) or manganese (Mn), but is not limited thereto.

The plurality of assembly electrode AE can include a plurality of first assembly electrode AE1, a plurality of second assembly electrode AE2, and a plurality of third assembly electrodes AE3 having different planar shapes. For example, the first assembly electrode AE1 can have a planar shape corresponding to the planar shape of the magnetic metal 127 of the first light emitting diode 120. The second assembly electrode AE2 can have a planar shape corresponding to the planar shape of the magnetic metal 137 of the second light emitting diode 130. The third assembly electrode AE3 can have a planar shape corresponding to the planar shape of the magnetic metal 147 of the third light emitting diode 140.

For example, when the planar shapes of the magnetic metals 127, 137, and 147 of the light emitting diodes LED and the assembly electrode AE match, the light emitting diode LED can be selectively assembled in the opening OLH where each assembly electrode AE is disposed.

Accordingly, in a first opening OLH1 in which the first assembly electrode AE1 is disposed, the first light emitting diode 120 is assembled. In a second opening OLH2 in which the second assembly electrode AE2 is disposed, the second light emitting diode 130 is assembled and in a third opening OLH3 in which the third assembly electrode AE3 is disposed, the third light emitting diode 140 can be assembled.

First, referring to FIG. 6A, a plurality of light emitting diodes LED which is grown on a wafer is put into a chamber CB filled with a fluid WT. The fluid WT can include water and a top of the chamber CB filled with fluid WT can be open.

Next, the assembling substrate 10 can be located on the chamber CB filled with the light emitting diode LED. The assembling substrate 10 can be disposed such that the organic layer OL on which the plurality of openings OLH of the assembling substrate 10 and the chamber CB face each other.

Therefore, the light emitting diodes LED which are sunken on the bottom of the chamber CB or float can move toward the assembling substrate 10 by a magnetic force generated between the assembly electrode AE exposed by the plurality of openings OLH and the light emitting diodes LED.

At this time, the light emitting diode LED can include magnetic materials to move by the magnetic field. For example, the magnetic metals 127, 137, and 147 of the light emitting diode LED include a paramagnetic material, such as aluminum (Al) or manganese (Mn) to align a direction of the light emitting diodes LED toward the assembly electrode AE.

Referring to FIG. 6B together, the light emitting diode LED moving toward the assembling substrate 10 by the assembly electrode AE can be self-assembled in the assembling substrate 10 by the magnetic force between the magnetic metals 127, 137, and 147 and the assembly electrode AE.

At this time, the first assembly electrode AE1 disposed in the first opening OLH1, the second assembly electrode AE2 disposed in the second opening OLH2, and the third assembly electrode AE3 disposed in the third opening OLH3 can be configured to have different planar shapes. Therefore, the assembly positions of the first light emitting diode 120, the second light emitting diode 130, and the third light emitting diode 140 can be distinguished. For example, according to the present disclosure, planar shapes of the magnetic metals 127, 137, and 147 are configured to be different for every light emitting diode LED which emits different color lights. The planar shape of the assembly electrode AE of the assembling substrate 10 is also configured to be different so as to correspond thereto. Therefore, when the planar shape of the magnetic metals 127, 137, and 147 and the assembly electrode AE match, the light emitting diode LED can be assembled in the opening OLH in which each assembly electrode AE is disposed. The first light emitting diode 120, the second light emitting diode 130, and the third light emitting diode 140 can be selectively assembled in positions of corresponding assembly grooves. The first light emitting diode 120, the second light emitting diode 130, and the third light emitting diode 140 which are disposed on the assembling substrate 10 as described above are transferred to the display device 100 or the assembling substrate 10 is directly configured as the display device 100 to product the display device 100.

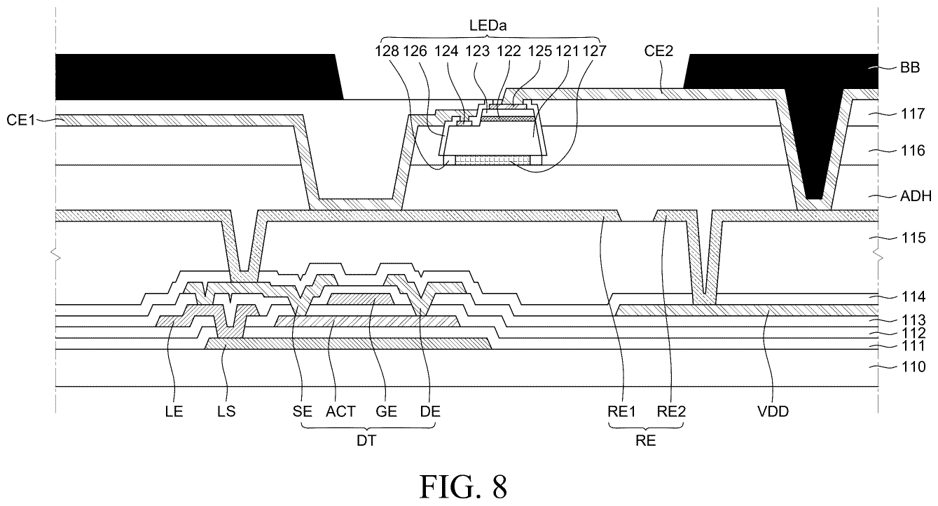

Hereinafter, referring to FIGS. 7 and 8, a display device 100 according to an example embodiment of the present disclosure which is manufactured using an assembling substrate 10 according to an example embodiment of the present disclosure will be described.

Particularly, FIG. 7 is a schematic diagram of a display device according to an example embodiment of the present disclosure. In FIG. 7, for the convenience of description, among various components of the display device 100, a display panel PN, a gate driver GD, a data driver DD, and a timing controller TC are illustrated.

Referring to FIG. 7, the display device 100 includes a display panel PN including a plurality of sub pixels SP, a gate driver GD and a data driver DD which supply various signals to the display panel PN, and a timing controller TC which controls the gate driver GD and the data driver DD.

A driver, such as a gate driver GD, a data driver DD, and a timing controller TC, can can be connected to the display panel PN in various ways. For example, the gate driver GD can be mounted in the non-active area NA in a gate in panel (GIP) manner or mounted between the plurality of sub pixels SP in the active area AA in a gate in active area (GIA) manner.

The display panel PN is a configuration which displays images to the user and includes the plurality of sub pixels SP. In the display panel PN, the plurality of scan lines SL and the plurality of data lines DL intersect each other and the plurality of sub pixels SP is connected to the scan lines SL and the data lines DL, respectively. In addition, each of the plurality of sub pixels SP can be connected to a high potential power line, a low potential power line, and a reference line.

In the display panel PN, an active area AA and a non-active area NA enclosing the active area AA can be defined.

The active area AA is an area in which images are displayed in the display device 100. In the active area AA, a plurality of sub pixels SP which configures a plurality of pixels and a circuit for driving the plurality of sub pixels SP can be disposed. The plurality of sub pixels SP is a minimum unit which configures the active area AA and n sub pixels SP can form one pixel. In each of the plurality of sub pixels SP, a light emitting diode and a thin film transistor for driving the light emitting diode can be disposed. The plurality of light emitting diodes can be defined in different manners depending on the type of the display panel PN. For example, when the display panel PN is an inorganic light emitting display panel, the light emitting diode can be a light emitting diode (LED) or a micro light emitting diode (LED).

In the active area AA, a plurality of signal lines which transmits various signals to the plurality of sub pixels SP is disposed. For example, the plurality of signal lines can include a plurality of data lines DL which supplies a data voltage to each of the plurality of sub pixels SP and a plurality of scan lines which supplies a gate voltage to each of the plurality of sub pixels SP. The plurality of scan lines SL extends to one direction in the active area AA to be connected to the plurality of sub pixels SP and the plurality of data lines DL extends to a direction different from the one direction in the active area AA to be connected to the plurality of sub pixels SP. In addition, in the active area AA, a low potential power line and a high potential power line can be further disposed, but are not limited thereto.

In the non-active area NA, images are not displayed, but a link line which transmits a signal to the sub pixel SP of the active area AA, a pad electrode, or a driving IC, such as a gate driver IC or a data driver IC, can be disposed.

The display panel PN includes a plurality of pixels which is formed by a plurality of sub pixels SP. Each of the plurality of sub pixels SP includes a light emitting diode LEDa and a pixel circuit to independently emit light. One pixel can include a first sub pixel, a second sub pixel, and a third sub pixel. For example, one pixel can be formed of one pair of first sub pixels, one pair of second sub pixels, and one pair of third sub pixels, but is not limited thereto. At this time, the first sub pixel can be a red sub pixel, the second sub pixel can be a green sub pixel, and the third sub pixel can be a blue sub pixel, but it is not limited thereto.

A plurality of light emitting diodes can be disposed in the plurality of sub pixels SP. For example, as it will be described below with reference to FIG. 3, the plurality of light emitting diodes LEDa can include a first light emitting diode, a second light emitting diode, and a third light emitting diode. In the first sub pixel, the first light emitting diode 120 is disposed, in the second sub pixel, the second light emitting diode 130 is disposed, and in the third sub pixel, the third light emitting diode 140 can be disposed. For example, the first light emitting diode 120 can be a red light emitting diode, the second light emitting diode 130 can be a green light emitting diode, and the third light emitting diode 140 can be a blue light emitting diode.

FIG. 8 is a cross-sectional view of a display device according to an example embodiment of the present disclosure. Particularly, FIG. 8 is a view illustrating a first sub pixel in which a first light emitting diode 120, among the light emitting diodes LEDa, is disposed as an example and can be substantially the same as the cross-sectional views of the second sub pixel in which the second light emitting diode 130 is disposed and the third sub pixel in which the third light emitting diode 140 is disposed.

Referring to FIG. 8, in each of the plurality of sub pixels SP of the display panel PN of the display device 100 according to the example embodiment of the present disclosure, a substrate 110, a buffer layer 111, a gate insulating layer 112, an interlayer insulating layer 113, a passivation layer 114, a first planarization layer 115, an adhesive layer ADH, a second planarization layer 116, a third planarization layer 117, a black bank BB, a driving transistor DT, a light emitting diode LEDa, a reflection electrode RE, a light shielding layer LS, an auxiliary electrode LE, a first connection electrode CE1, a second connection electrode CE2, and a power line VDD can be disposed.

First, the substrate 110 is a component for supporting various components included in the display device 100 and can be formed of an insulating material. For example, the substrate 110 can be formed of glass or resin. Further, the substrate 110 can be configured to include a polymer or plastics or can be formed of a material having flexibility.

The light shielding layer LS can be disposed in each of the plurality of sub pixels SP on the substrate 110. The light shielding layer LS blocks light incident onto an active layer ACT of the driving transistor DT to be described below from a lower portion the substrate 110. Light which is incident onto the active layer ACT of the driving transistor DT is blocked by the light shielding layer LS to minimize or reduce a leakage current.

The buffer layer 111 can be disposed on the substrate 110 and the light shielding layer LS. The buffer layer 111 can reduce permeation of moisture or impurities through the substrate 110. The buffer layer 111 can be configured by a single layer or a double layer of silicon oxide (SiOx) or silicon nitride (SiNx), but is not limited thereto. However, the buffer layer 111 can be omitted depending on a type of substrate 110 or a type of transistor, but is not limited thereto.

The driving transistor DT can be disposed on the buffer layer 111. The driving transistor DT includes an active layer ACT, a gate electrode GE, a source electrode SE, and a drain electrode DE.

The active layer ACT can be disposed on the buffer layer 111. The active layer ACT can be formed of a semiconductor material, such as an oxide semiconductor, amorphous silicon, or polysilicon, but is not limited thereto.

The gate insulating layer 112 can be disposed on the active layer ACT. The gate insulating layer 112 is an insulating layer which insulates the active layer ACT from the gate electrode GE and can be configured by a single layer or a double layer of silicon oxide (SiOx) or silicon nitride (SiNx), but is not limited thereto.

The gate electrode GE can be disposed on the gate insulating layer 112. The gate electrode GE can be configured by a conductive material, such as copper (Cu), aluminum (Al), molybdenum (Mo), nickel (Ni), titanium (Ti), chrome (Cr), or an alloy thereof, but is not limited thereto.

The interlayer insulating layer 113 can be disposed on the gate electrode GE. In gate insulating layer 112 and the interlayer insulating layer 113, a contact hole through which the source electrode SE and the drain electrode DE are connected to the active layer ACT is formed. The interlayer insulating layer 113 is an insulating layer which protects components below the interlayer insulating layer 113 and can be configured by a single layer or a double layer of silicon oxide (SiOx) or silicon nitride (SiNx), but is not limited thereto.

The source electrode SE and the drain electrode DE which are electrically connected to the active layer ACT can be disposed on the interlayer insulating layer 113. The source electrode SE and the drain electrode DE can be configured by a conductive material, such as copper (Cu), aluminum (Al), molybdenum (Mo), nickel (Ni), titanium (Ti), chrome (Cr), or an alloy thereof, but are not limited thereto.

In the meantime, in the present disclosure, it is described that the interlayer insulating layer 113, For example, only one insulating layer is disposed between the gate electrode GE and the source electrode SE and the drain electrode DE. However, a plurality of insulating layers can be disposed between the gate electrode GE and the source electrode SE and the drain electrode DE, but are not limited thereto.

Further, the pixel circuit can further include a switching transistor, a sensing transistor, and an emission control transistor, in addition to the driving transistor DT, and is not limited thereto.

The auxiliary electrode LE can be disposed on the gate insulating layer 112. The auxiliary electrode LE is an electrode which electrically connects the light shielding layer LS below the buffer layer 111 to any one of the source electrode SE of the driving transistor DT and the drain electrode DE of the driving transistor DT on the interlayer insulating layer 113. For example, the light shielding layer LS is electrically connected to any one of the source electrode SE or the drain electrode DE of the driving transistor DT through the auxiliary electrode LE so as not to operate as a floating gate. Therefore, fluctuation of a threshold voltage of the driving transistor DT caused by the floated light shielding layer LS can be minimized or reduced. Even though in the drawing, the light shielding layer LS is connected to the source electrode SE of the driving transistor DT, the light shielding layer LS can also be connected to the drain electrode DE of the driving transistor DT, but is not limited thereto.

The power line VDD can be disposed on the interlayer insulting layer 113. The power line VDD is electrically connected to the light emitting diode LEDa together with the driving transistor DT to allow the light emitting diode LEDa to emit light. The power line VDD can be configured by a conductive material such as copper (Cu), aluminum (Al), molybdenum (Mo), nickel (Ni), titanium (Ti), chrome (Cr), or an alloy thereof, but is not limited thereto.

The passivation layer 114 can be disposed on the driving transistor DT and the power line VDD. The passivation layer 114 can protect the driving transistor DT and the power line VDD from permeation of moisture or impurity. For example, the passivation layer 114 can be configured by a single layer or a double layer of silicon oxide (SiOx) or silicon nitride (SiNx), but is not limited thereto. However, the passivation layer 114 can be omitted depending on a type of substrate 110 or a type of transistor, but is not limited thereto.

The first planarization layer 115 can be disposed on the passivation layer 114. The first planarization layer 115 can planarize an upper portion of the substrate 110 on which the driving transistor DT is disposed. The first planarization layer 115 can be configured by a single layer or a double layer, and for example, can be formed of photoresist or an acrylic organic material, but is not limited thereto.

A plurality of reflection electrodes RE which is spaced apart from each other can be disposed on the first planarization layer 115. The plurality of reflection electrodes RE electrically connects the light emitting diode LEDa to the power line VDD and the driving transistor DT and can serve as a reflector which reflects light emitted from the light emitting diode LEDa to the upper portion of the light emitting diode LEDa. The plurality of reflection electrodes RE is formed of a conductive material having the excellent reflecting property to reflect light emitted from the light emitting diode LEDa toward the upper portion of the light emitting diode LEDa. Therefore, the plurality of reflection electrodes RE can include various conductive layers in consideration of a light reflection efficiency and a resistance. For example, a reflective plate can use an opaque conductive layer, such as silver (Ag), aluminum (Al), molybdenum (Mo), titanium (Ti), or an alloy thereof, and a transparent conductive layer, such as indium tin oxide (ITO), but the structure and the material of the reflection electrode RE are not limited thereto.

The plurality of reflection electrodes RE can include a first reflection electrode RE1 and a second reflection electrode RE2. The first reflection electrode RE1 can electrically connect the driving transistor DT and the light emitting diode LEDa. The first reflection electrode RE1 can be connected to the source electrode SE or the drain electrode DE of the driving transistor DT through a contact hole formed in the passivation layer 114 and the first planarization layer 115. The first reflection electrode RE1 can be electrically connected to the first electrode 124 of the light emitting diode LEDa through the first connection electrode CE1.

The second reflection electrode RE2 can electrically connect the power line VDD and the light emitting diode LEDa. The second reflection electrode RE2 can be connected to the power line VDD through a contact hole formed in the passivation layer 114 and the first planarization layer 115 and can be electrically connected to the second electrode 125 of the light emitting electrode LEDa through a second connection electrode CE2 to be described below.

The adhesive layer ADH can be disposed on the plurality of reflection electrodes RE. The adhesive layer ADH is formed on the front surface of the substrate 110 to fix the light emitting diode LEDa disposed on the adhesive layer ADH. The adhesive layer ADH can be formed of a photo curable or thermo-setting adhesive material which is hardened by light or heat. For example, the adhesive layer ADH can be formed of an acrylic material including a photoresist, but is not limited thereto.

The plurality of light emitting diodes LEDa can be disposed in each of the plurality of sub pixels SP on the adhesive layer ADH. The plurality of light emitting diodes LEDa is elements which emit light by a current and can include light emitting diodes LEDa which emit red light, green light, and blue light and implement various color light including white by a combination thereof. For example, the plurality of light emitting diodes LEDa can be light emitting diodes (LED) or a micro LEDs, but is not limited thereto.

The light emitting diode LEDa is disposed on the adhesive layer ADH so that the insulating layer 128 disposed below the light emitting diode ADH is in contact with the adhesive layer ADH, but is not limited thereto.

The second planarization layer 116 can be disposed on the adhesive layer ADH. The second planarization layer 116 is disposed so as to enclose a part of side surfaces of the plurality of light emitting diodes LEDa to fix and protect the plurality of light emitting diodes LEDa.

In the meantime, the second planarization layer 116 can be lower than a height of the first electrode 124. For example, the thickness of the second planarization layer 116 can be adjusted by performing the ashing process. For example, after applying a material layer of the second planarization layer 116 so as to cover the light emitting diode LEDa, the ashing process is performed to reduce the overall thickness of the material layer of the second planarization layer 116 to form the height of the second planarization layer 116 to be lower than the height of the first electrode 124. Therefore, the second planarization layer 116 can expose the first electrode 124. Accordingly, the first connection electrode CE1 disposed on the second planarization layer 116 can be easily connected to the first electrode 124 without a separate contact hole.

The second planarization layer 116 can be configured by a single layer or a double layer, and for example, can be formed of photoresist or an acrylic organic material, but is not limited thereto.

The first connection electrode CE1 can be disposed on the second planarization layer 116. The first connection electrode CE1 is an electrode which is disposed in each of the plurality of sub pixels SP to electrically connect the light emitting diode LEDa and the driving transistor DT. The first connection electrode CE1 can be connected to the first reflection electrode RE1 through the contact hole formed in the second planarization layer 116 and the adhesive layer ADH. Accordingly, the first connection electrode CE1 can be electrically connected to any one of the source electrode SE and the drain electrode DE of the driving transistor DT through the first reflection electrode RE1. For example, the first connection electrode CE1 can connect the first electrode 124 of the light emitting diode LEDa to the source electrode SE of the driving transistor DT, but it is not limited thereto. The first connection electrode CE1 can be formed of, for example, a transparent conductive material, such as indium tin oxide (ITO) or indium zinc oxide (IZO), but is not limited thereto.

The third planarization layer 117 can be disposed on the second planarization layer 116 and the plurality of first connection electrodes CE1. The third planarization layer 117 planarizes an upper portion of the substrate 110 in which the light emitting diodes LEDa is disposed together with the second planarization layer 116 and fixes the light emitting diodes LEDa onto the substrate 110 together with the adhesive layer AD.

Further, the third planarization layer 117 is disposed so as to cover the first connection electrode CE1 to separate the first connection electrode CE1 from the second connection electrode CE2. Therefore, the short of the first connection electrode CE1 and the second connection electrode CE2 can be suppressed.

The second connection electrode CE2 can be disposed on the third planarization layer 117. The second connection electrode CE2 is an electrode for electrically connecting the light emitting diode LEDa and the power line VDD. The second connection electrode CE2 can be connected to the second reflection electrode RE2 through the contact hole formed in the third planarization layer 117, the second planarization layer 1116, and the adhesive layer ADH. Accordingly, the second connection electrode CE2 can be electrically connected to the power line VDD through the second reflection electrode RE2. For example, the second connection electrode CE2 can connect the second electrode 125 of the light emitting diode LEDa to the power line VDD, but it is not limited thereto.

The black bank BB can be disposed on the third planarization layer 117 and the second connection electrode CE2. The black bank BB can be disposed so as not to overlap the light emitting diode LEDa to define an emission area. For example, the black bank BB covers an edge of the second connection electrode CE2 which is connected to the light emitting diode LEDa to define the emission area. For example, the black bank BB can divide the plurality of sub pixels SP. The black bank BB can be formed of an insulating material to insulate the second connection electrodes CE2 of adjacent sub pixels SP from each other. Further, the black bank BB can include a black component having high light absorptance to suppress color mixture between adjacent sub pixels SP. The black bank BB can be formed of a polyimide resin, an acrylic resin, or a benzocyclobutene (BCB) resin, but is not limited thereto.

The display device 100 according to the example embodiment of the present disclosure can include a plurality of light emitting diodes LEDa having the same planar shape and size regardless of a color of emitted light. At this time, the magnetic metals 127, 137, and 147 of the light emitting diodes LEDa are configured to have different planar shapes to distinguish the light emitting diodes LEDa during the self-assembly. Therefore, a first light emitting diode 120, a second light emitting diode 130, and a third light emitting diode 140 which emit different color lights can be selectively assembled in positions of corresponding assembly grooves on the assembling substrate 10. For example, in the display device 100 according to the example embodiment of the present disclosure, the assembly position of each light emitting diode LEDa can be controlled by giving the exclusiveness to the planar shapes of the magnetic metals 127, 137, and 147 of the light emitting diodes LEDa. Accordingly, in the display device 100 according to the example embodiment of the present disclosure, even though light emitting diodes LEDa having the same size are mixed in one tray as the light emitting diode LEDa, the plurality of light emitting diodes LEDa which emit different color lights can be selectively assembled to be simultaneously assembled. Therefore, as compared with an example that the self-assembly is performed by filling only the light emitting diodes which emit one same color light in one tray, the number of times of performing an assembling process can be reduced. Therefore, the production efficiency can be improved and a manufacturing cost can be saved.

Further, in the display device 100 according to the example embodiment of the present disclosure, regardless of the color of emitted light, all the light emitting diodes LEDa have the same size so that there is no need to provide a separate mask for manufacturing the light emitting diodes LEDa depending on the color of emitted light. Therefore, the manufacturing cost can be saved. Further, there is no need to manage the size exclusiveness between light emitting diodes LEDa which emit different color lights and further the size uniformity between the light emitting diodes LEDa can be relatively easily managed to improve the production efficiency of the light emitting diode LEDa.

Furthermore, in the display device 100 according to the example embodiment of the present disclosure, the light emitting diodes LEDa can include insulating layers 128, 138, and 148 which are disposed so as to enclose the side surfaces of the magnetic metals 127, 137 and 147. The insulating layers 128, 138, and 148 are disposed so as to enclose the first semiconductor layer 121 exposed by the magnetic metals 127, 137, and 147 to alleviate the steps between the magnetic metals 127, 137, and 147 and the first semiconductor layer 121 and protect the magnetic metals 127, 137, and 147. Therefore, the breakage defect of the light emitting diodes LEDs which can occur during the assembling process can be minimized or reduced.

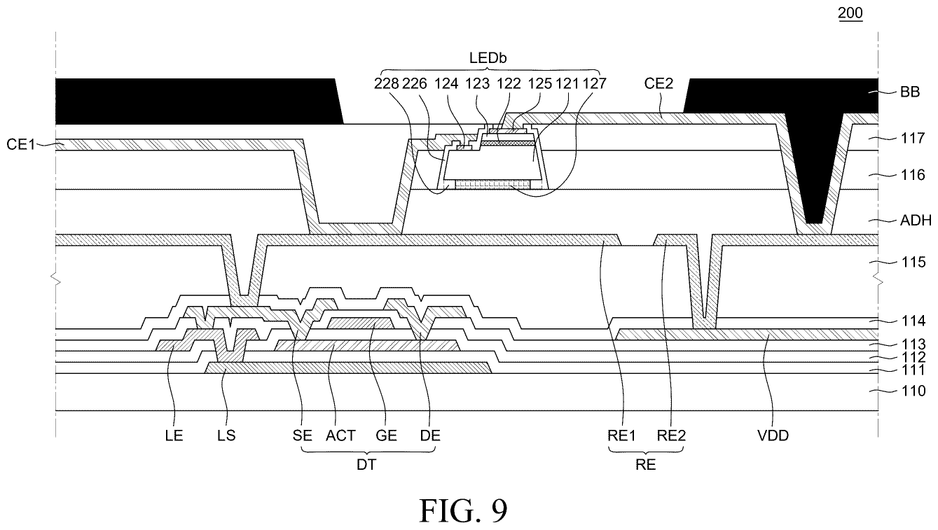

FIG. 9 is a cross-sectional view of a display device according to another example embodiment of the present disclosure. Components of a display device 200 of FIG. 9 are substantially the same as the display device 100 of FIGS. 7 and 8 except for a light emitting diode LEDb so that a redundant description will be omitted or briefly provided.

Referring to FIG. 9, the passivation film 226 of the light emitting diode LEDb can be integrally formed with the insulating layer 228. For example, the passivation film 226 and the insulating layer 228 can be simultaneously formed by one process to be formed of the same material. Therefore, the passivation film 226 can be disposed so as to cover not only the first semiconductor layer 121, the emission layer 122, the second semiconductor layer 123, the first electrode 124, and the second electrode 125, but also a side surface of the insulating layer 228.

For example, the passivation film 226 and the insulating layer 228 can be formed of the same insulating material. Therefore, the first semiconductor layer 121, the emission layer 122, the second semiconductor layer 123, and the magnetic metal 127 can be protected and the step between the magnetic metal 127 and the first semiconductor layer 121 can be planarized, concurrently.

For example, the passivation film 226 and the insulating layer 228 can be configured by transparent epoxy, alumina (Al2O3), silicon oxide (SiOx), or silicon nitride (SiNx), but is not limited thereto.

The display device 200 according to another example embodiment of the present disclosure can include a plurality of light emitting diodes LEDb having the same planar shape and size regardless of a color of emitted light. At this time, the magnetic metals 127, 137, and 147 of the light emitting diodes LEDb are configured to have different planar shapes to distinguish the light emitting diodes LEDb during the self-assembly. Therefore, a first light emitting diode, a second light emitting diode, and a third light emitting diode which emit different color lights can be selectively assembled in positions of corresponding assembly grooves. For example, in the display device 200 according to the another example embodiment of the present disclosure, the assembly position of each light emitting diode LEDb can be controlled by giving the exclusiveness to the planar shapes of the magnetic metals 127, 137, and 147 of the light emitting diodes LEDb. Accordingly, in the display device 200 according to another example embodiment of the present disclosure, even though light emitting diodes LEDb having the same size are mixed in one tray as the light emitting diode LEDb, the plurality of light emitting diodes LEDb which emit different color lights can be selectively assembled to be simultaneously assembled. Therefore, as compared with an example that the self-assembly is performed by filling only the light emitting diodes which emit one same color light in one tray, the number of times of performing an assembling process can be reduced. Therefore, the production efficiency can be improved and a manufacturing cost can be saved.

Further, in the display device 200 according to another example embodiment of the present disclosure, regardless of the color of emitted light, all the light emitting diodes LEDb have the same size so that there is no need to provide a separate mask for manufacturing the light emitting diodes LEDb depending on the color of emitted light. Therefore, the manufacturing cost can be saved. Further, there is no need to manage the size exclusiveness between light emitting diodes LEDb which emit different color lights and further the size uniformity between the light emitting diodes LEDb can be relatively easily managed to improve the production efficiency of the light emitting diode LEDb.

Further, in the display device 200 according to another example embodiment of the present disclosure, the light emitting diode LEDb can include an insulating layer 228 which are disposed so as to enclose the side surfaces of the magnetic metals 127, 137 and 147. The insulating layer 228 is disposed so as to enclose the first semiconductor layer 121 exposed by the magnetic metals 127, 137, and 147 to alleviate the steps between the magnetic metals 127, 137, and 147 and the first semiconductor layer 121 and protect the magnetic metals 127, 137, and 147. Therefore, the breakage defect of the light emitting diodes LEDb which can occur during the assembling process can be minimized or reduced.

Specifically, in the display device 200 according to another example embodiment of the present disclosure, the passivation film 226 of the light emitting diode LEDb can be integrally formed with the insulating layer 228. For example, the passivation film 226 and the insulating layer 228 can be simultaneously formed by one process. Therefore, a process for separately forming the passivation film 226 and the insulating layer 228 can be omitted. Therefore, the production efficiency can be improved and a manufacturing cost can be saved.

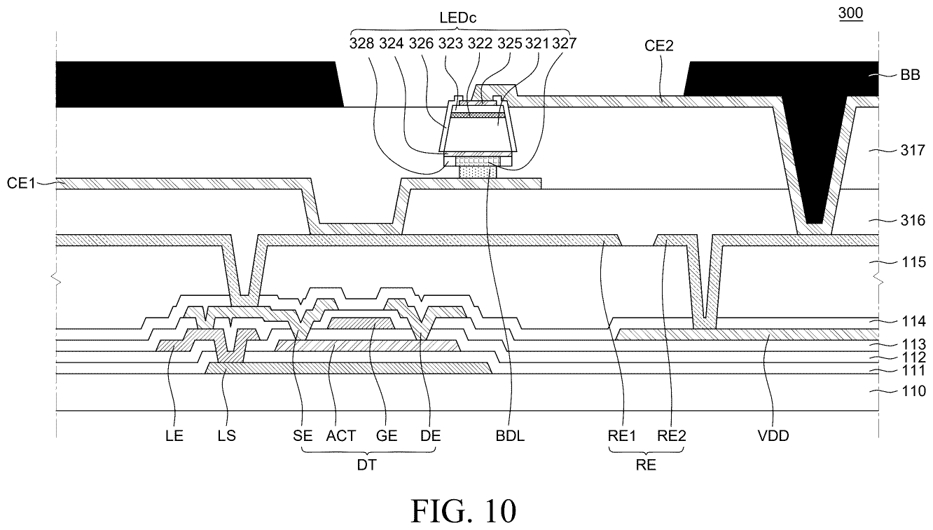

FIG. 10 is a cross-sectional view of a display device according to still another example embodiment of the present disclosure. Components of a display device 300 of FIG. 10 are substantially the same as the display device 100 of FIGS. 7 and 8 except for whether there is an adhesive layer ADH and a bonding layer BDL, a first connection electrode CE1, a light emitting diode LEDc, a second planarization layer 316, and a third planarization layer 317. Therefore, a redundant description will be omitted or briefly provided

Referring to FIG. 10, the second planarization layer 316 can be disposed on the plurality of reflection electrodes RE. Together with the first planarization layer 115, the second planarization layer 316 can planarize an upper portion of the substrate 110 on which the driving transistor DT is disposed. The second planarization layer 316 can be configured by a single layer or a double layer, and for example, can be formed of photoresist or an acrylic organic material, but is not limited thereto.

The first connection electrode CE1 can be disposed on the second planarization layer 316. The first connection electrode CE1 is an electrode which is disposed in each of the plurality of sub pixels SP to electrically connect the light emitting diode LEDc and the driving transistor DT. The first connection electrode CE1 can be connected to the first reflection electrode RE1 through the contact hole formed in the second planarization layer 316. Accordingly, the first connection electrode CE1 can be electrically connected to any one of the source electrode SE and the drain electrode DE of the driving transistor DT through the first reflection electrode RE1. For example, the first connection electrode CE1 can connect the first electrode 324 of the light emitting diode LEDc to the source electrode SE of the driving transistor DT, but it is not limited thereto. The first connection electrode CE1 can be formed of, for example, a transparent conductive material, such as indium tin oxide (ITO) or indium zinc oxide (IZO), but is not limited thereto.

A bonding layer BDL can be disposed on the first connection layer CE1. The bonding layer BDL can fix the light emitting diode LEDc disposed on the first connection electrode CE1. For example, the first connection electrode CE1 and the magnetic metal 327 of the light emitting diode LEDc can be electrically connected by eutectic bonding using the bonding layer BDL. For example, the bonding layer BDL and the first connection electrode CE1 can be bonded by applying heat and pressure. Therefore, the light emitting diode LEDc can be bonded to the bonding layer BDL and the first connection electrode CE1 by eutectic bonding without using a separate adhering material, but is not limited thereto.

The light emitting diode LEDc can be disposed on the bonding layer BDL. The light emitting diode LEDc includes a first semiconductor layer 321, an emission layer 322, a second semiconductor layer 323, a first electrode 324, a second electrode 325, a passivation film 326, a magnetic metal 327, and an insulating layer 328.

The first electrode 324 can be disposed below the first semiconductor layer 321. The first semiconductor layer 321 is a semiconductor layer doped with an n-type impurity and the first electrode 324 can be a cathode. The first electrode 324 can be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The passivation film 326 which encloses the first semiconductor layer 321, the emission layer 322, the second semiconductor layer 323, and the second electrode 325 can be disposed. The passivation film 326 is formed of an insulating material to protect the first semiconductor layer 321, the emission layer 322, and the second semiconductor layer 323. For example, the passivation film 326 can be configured by transparent epoxy, alumina (Al2O3), silicon oxide (SiOx), or silicon nitride (SiNx), but is not limited thereto. A contact hole which exposes the second electrode 325 can be formed in the passivation film 326.

The magnetic metal 327 can be disposed below the first electrode 324. The magnetic metal 327 can include a magnetic material to move by a magnetic field. For example, the magnetic metal 327 of the light emitting diode LEDc includes a paramagnetic material, such as aluminum (Al) or manganese (Mn) to align a direction of the light emitting diodes LEDc.

The magnetic metal 327 is disposed below the first electrode 324 to electrically contact with the first electrode 324. For example, an area of the magnetic metal 327 can be smaller than an area of the first electrode 324. Therefore, the magnetic metal 327 can expose at least a part of a bottom surface of the first electrode 324, but is not limited thereto.

The insulating layer 328 can be disposed below the first electrode 324. The insulating layer 328 is disposed so as to enclose a side surface of the magnetic metal 327 to planarize a step between the magnetic metal 327 and the first electrode 324 and protect the magnetic metal 327, concurrently. Therefore, the insulating layer 328 can be disposed so as to cover the first electrode 324 which is exposed by the magnetic metal 327. Accordingly, an end of the insulating layer 328 can be disposed on the same plane as an end of the first electrode 324, but is not limited thereto.

Therefore, the insulating layer 328 can be disposed to be spaced apart from the passivation film 326. For example, the insulating layer 328 can be separately formed from the passivation film 326 to be spaced apart from the passivation film 326, but is not limited thereto.

For example, the insulating layer 328 can be formed of an inorganic insulating material, such as silicon oxide (SiOx) or silicon nitride (SiNx), but is not limited thereto and can be formed of an organic material.

The second planarization layer 316 can be disposed on the first connection electrode CE1. The second planarization layer 316 is disposed so as to enclose a part of side surfaces of the plurality of light emitting diodes LEDc to fix and protect the plurality of light emitting diodes LEDc.

The second planarization layer 316 can be configured by a single layer or a double layer, and for example, can be formed of photoresist or an acrylic organic material, but is not limited thereto.

The third planarization layer 317 can be disposed on the second planarization layer 316 and the plurality of first connection electrodes CE1. The third planarization layer 317 can planarize an upper portion of the substrate 110 in which the light emitting diode LEDc is disposed together with the second planarization layer 316 and can fix the light emitting diode LEDc onto the substrate 110.

Further, the third planarization layer 317 is disposed so as to cover the first connection electrode CE1 to separate the first connection electrode CE1 from the second connection electrode CE2. Therefore, the short of the first connection electrode CE1 and the second connection electrode CE2 can be suppressed.

The second connection electrode CE2 can be disposed on the third planarization layer 317. The second connection electrode CE2 is an electrode for electrically connecting the light emitting diode LEDc and the power line VDD. The second connection electrode CE2 can be connected to the second reflection electrode RE2 through the contact holes formed in the third planarization layer 317 and the second planarization layer 316. Accordingly, the second connection electrode CE2 can be electrically connected to the power line VDD through the second reflection electrode RE2. For example, the second connection electrode CE2 can connect the second electrode 325 of the light emitting diode LEDc to the power line VDD, but it is not limited thereto.

The black bank BB can be disposed on the third planarization layer 317 and the second connection electrode CE2. The black bank BB is disposed so as not to overlap the light emitting diode LEDc to define an emission area. For example, the black bank BB covers an edge of the second connection electrode CE2 which is connected to the light emitting diode LEDc to define the emission area. For example, the black bank BB can divide the plurality of sub pixels SP. The black bank BB can be formed of an insulating material to insulate the second connection electrodes CE2 of adjacent sub pixels SP from each other. Further, the black bank BB can include a black component having high light absorptance to suppress color mixture between adjacent sub pixels SP. The black bank BB, for example, can be formed of a polyimide resin, an acrylic resin, or a benzocyclobutene (BCB) resin, but is not limited thereto.

The display device 300 according to still another example embodiment of the present disclosure can include a plurality of light emitting diodes LEDc having the same planar shape and size regardless of a color of emitted light. At this time, the magnetic metals 327 of the light emitting diodes LEDc are configured to have different planar shapes to distinguish the light emitting diodes LEDc during the self-assembly. Therefore, a first light emitting diode, a second light emitting diode, and a third light emitting diode which emit different color lights can be selectively assembled on the assembling substrate 10 in positions of corresponding assembly grooves. For example, in the display device 300 according to still another example embodiment of the present disclosure, the assembly position of each light emitting diode LEDc can be controlled by giving the exclusiveness to the planar shapes of the magnetic metal 327 of light emitting diode LEDc. Accordingly, in the display device 300 according to still another example embodiment of the present disclosure, even though light emitting diodes LEDc having the same size are mixed in one tray as the light emitting diode LEDc, the plurality of light emitting diodes LEDc which emit different color lights can be selectively assembled to be simultaneously assembled. Therefore, as compared with an example that the self-assembly is performed by filling only the light emitting diodes which emit one same color light in one tray, the number of times of performing an assembling process can be reduced. Therefore, the production efficiency can be improved and a manufacturing cost can be saved.

Further, in the display device 300 according to still another example embodiment of the present disclosure, regardless of the color of emitted light, all the light emitting diodes LEDc have the same size so that there is no need to provide a separate mask for manufacturing the light emitting diodes LEDc depending on the color of emitted light. Therefore, the manufacturing cost can be saved. Further, there is no need to manage the size exclusiveness between light emitting diodes LEDc which emit different color lights and further the size uniformity between the light emitting diodes LEDc can be relatively easily managed to improve the production efficiency of the light emitting diode LEDc.

Further, in the display device 300 according to still another example embodiment of the present disclosure, the light emitting diodes LEDc can include insulating layers 328 which are disposed so as to enclose the side surfaces of the magnetic metals 327. The insulating layer 328 is disposed so as to cover the first electrode 324 exposed by the magnetic metal 327 to alleviate the step between the magnetic metal 327 and the first electrode 324 and protect the magnetic metal 327, concurrently. Therefore, the breakage defect of the light emitting diode LEDc which can occur during the assembling process can be minimized or reduced.

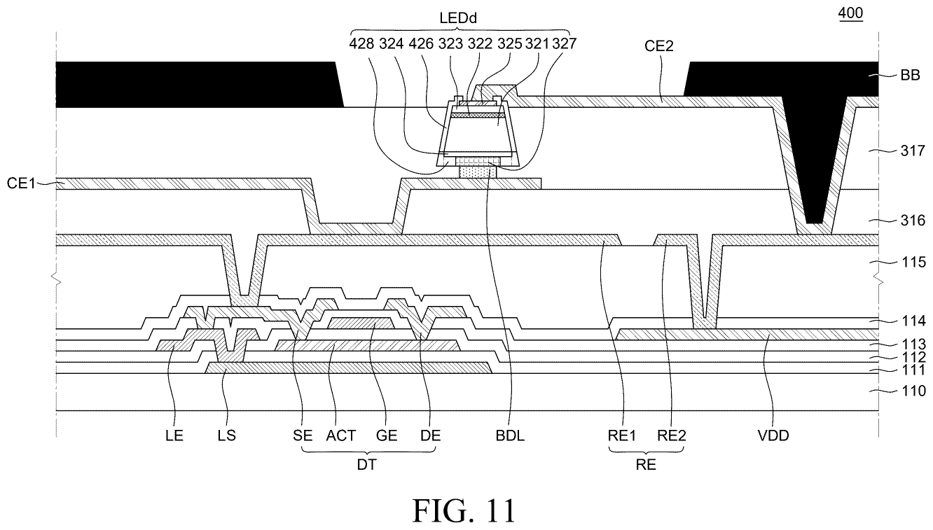

FIG. 11 is a cross-sectional view of a display device according to still another example embodiment of the present disclosure. Components of a display device 400 of FIG. 11 are substantially the same as the display device 300 of FIG. 10 except for a light emitting diode LEDd so that a redundant description will be omitted or briefly provided.

Referring to FIG. 11, a passivation film 426 can be integrally formed with an insulating layer 428. For example, the passivation film 426 and the insulating layer 428 are simultaneously formed by one process to be formed of the same material. Therefore, the passivation film 426 can be disposed so as to cover not only the first semiconductor layer 321, the emission layer 322, the second semiconductor layer 323, the first electrode 324, and the second electrode 325, but also a side surface of the insulating layer 428.

For example, the passivation film 426 and the insulating layer 428 are formed of the same insulating material so that the first semiconductor layer 321, the emission layer 322, the second semiconductor layer 323, and the magnetic metal 327 can be protected and the step between the magnetic metal 327 and the first electrode 324 can be planarized, concurrently.

For example, the passivation film 426 and the insulating layer 428 can be configured by transparent epoxy, alumina (Al2O3), silicon oxide (SiOx), or silicon nitride (SiNx), but is not limited thereto.

The display device 400 according to still another example embodiment of the present disclosure can include a plurality of light emitting diodes LEDd having the same planar shape and size regardless of a color of emitted light. At this time, the magnetic metals 327 of the light emitting diodes LEDd are configured to have different planar shapes to distinguish the light emitting diodes LEDd during the self-assembly. Therefore, a first light emitting diode, a second light emitting diode, and a third light emitting diode which emit different color lights can be selectively assembled in positions of corresponding assembly grooves. For example, in the display device 400 according to still another example embodiment of the present disclosure, the assembly position of each light emitting diode LEDd can be controlled by giving the exclusiveness to the planar shapes of the magnetic metal 327 of light emitting diode LEDd. Accordingly, in the display device 400 according to still another example embodiment of the present disclosure, even though light emitting diodes LEDd having the same size are mixed in one tray as the light emitting diode LEDd, the plurality of light emitting diodes LEDd which emit different color lights can be selectively assembled to be simultaneously assembled. Therefore, as compared with an example that the self-assembly is performed by filling only the light emitting diodes which emit one same color light in one tray, the number of times of performing an assembling process can be reduced. Therefore, the production efficiency can be improved and a manufacturing cost can be saved.

In the display device 400 according to still another example embodiment of the present disclosure, regardless of the color of emitted light, all the light emitting diodes LEDd have the same size so that there is no need to provide a separate mask for manufacturing the light emitting diodes LEDd depending on the color of emitted light. Therefore, the manufacturing cost can be saved. Further, there is no need to manage the size exclusiveness between light emitting diodes LEDd which emit different color lights and further the size uniformity between the light emitting diodes LEDd can be relatively easily managed to improve the production efficiency of the light emitting diode LEDd.

Further, in the display device 400 according to still another example embodiment of the present disclosure, the light emitting diodes LEDd can include insulating layers 428 which are disposed so as to enclose the side surfaces of the magnetic metals 327. The insulating layer 428 is disposed so as to cover the first electrode 324 exposed by the magnetic metal 327 to alleviate the step between the magnetic metal 327 and the first electrode 324 and protect the magnetic metal 327. Therefore, the breakage defect of the light emitting diode LEDd which can occur during the assembling process can be minimized or reduced.

Specifically, in the display device 400 according to still another example embodiment of the present disclosure, the passivation film 426 of the light emitting diode LEDd can be integrally formed with the insulating layer 428. For example, the passivation film 426 and the insulating layer 428 can be simultaneously formed by one process. Therefore, a process for separately forming the passivation film 426 and the insulating layer 428 can be omitted. Therefore, the production efficiency can be improved and a manufacturing cost can be saved.

The example embodiments of the present disclosure can also be described as follows:

According to aspects of the present disclosure, there is provided a light emitting diode. The light emitting diode includes a first semiconductor layer, an emission layer disposed on the first semiconductor layer, a second semiconductor layer disposed on the emission layer, a magnetic metal disposed below the first semiconductor layer and an insulating layer disposed to enclose a side surface of the magnetic metal.

The magnetic metal can be in contact with the first semiconductor layer and an area of the magnetic metal can be smaller than an area of the first semiconductor layer.

An end of the insulating layer can be disposed on the same plane as an end of the first semiconductor layer.

The light emitting diode can further include a first electrode disposed on the first semiconductor layer, a second electrode disposed on the second semiconductor layer and a passivation film disposed to enclose the first semiconductor layer, the emission layer, the second semiconductor layer, a part of the first electrode, and a part of the second electrode. The passivation film can be disposed to be spaced apart from the insulating layer.

The light emitting diode can further include a first electrode disposed on the first semiconductor layer, a second electrode disposed on the second semiconductor layer and a passivation film disposed to enclose the first semiconductor layer, the emission layer, the second semiconductor layer, a part of the first electrode, a part of the second electrode, and a side surface of the insulating layer. The passivation film can be integrally formed with the insulating layer.

The light emitting diode can further include a first electrode disposed between the first semiconductor layer and the magnetic metal and the insulating layer and a second electrode disposed on the second semiconductor layer. An area of the magnetic metal can be smaller than an area of the first electrode.

An end of the insulating layer can be disposed on the same plane as an end of the first electrode.

The light emitting diode can further include a passivation film disposed to enclose side surfaces of the first semiconductor layer, the emission layer, and the second semiconductor layer. The passivation film can be disposed to be spaced apart from the insulating layer.

The light emitting diode can further include a passivation film disposed to enclose side surfaces of the first electrode, the first semiconductor layer, the emission layer, the second semiconductor layer, and the insulating layer. The passivation film can be integrally formed with the insulating layer.

The magnetic metal can be formed of a paramagnetic material.

According to another aspect of the present disclosure, there is provided a substrate for assembling a light emitting diode. The substrate for assembling a light emitting diode includes a base substrate, a plurality of assembly electrodes disposed on the base substrate and an organic layer which is disposed on the base substrate and includes a plurality of openings which exposes the plurality of assembly electrodes. The plurality of assembly electrodes includes a plurality of first assembly electrodes, a plurality of second assembly electrodes, and a plurality of third assembly electrodes having different planar shapes.

The plurality of assembly electrodes can be formed of a paramagnetic material.

According to yet another aspect of the present disclosure, there is provided a display device. The display device includes a substrate in which a plurality of sub pixels is defined, a power line disposed on the substrate, a plurality of transistors disposed in each of the plurality of sub pixels on the substrate and a plurality of light emitting diodes which is disposed in each of the plurality of sub pixels on the power line and the plurality of transistors. The plurality of light emitting diodes includes a first light emitting diode, a second light emitting diode, and a third light emitting diode which emit different color lights. The plurality of light emitting diodes includes a first semiconductor layer, an emission layer disposed on the first semiconductor layer, a second semiconductor layer disposed on the emission layer, a magnetic metal disposed below the first semiconductor layer, and an insulating layer disposed so as to enclose a side surface of the magnetic metal. A magnetic metal of the first light emitting diode, a magnetic metal of the second light emitting diode, and a magnetic metal of the third light emitting diode have different planar shapes.

The first light emitting diode, the second light emitting diode, and the third light emitting diode can have the same size and the same planar shape. The magnetic metal of the first light emitting diode, the magnetic metal of the second light emitting diode, and the magnetic metal of the third light emitting diode can have the same shape and different positions.

The first light emitting diode, the second light emitting diode, and the third light emitting diode can have the same size and the same planar shape. The first light emitting diode, the second light emitting diode, and the third light emitting diode can have different sizes and different shapes.

The display device can further include a first planarization layer disposed on the plurality of transistors and the power line, the plurality of light emitting diodes being disposed on the first planarization layer and a second planarization layer which is disposed on the first planarization layer and is disposed so as to enclose the plurality of light emitting diodes. The insulating layer can be in contact with the second planarization layer.

Each of the plurality of light emitting diodes can further include a first electrode disposed between the first semiconductor layer and the magnetic metal and a second electrode disposed on the second semiconductor layer. The display device can further include a first connection electrode which is disposed between the plurality of light emitting diodes and the first planarization layer and connects the first electrode and the plurality of transistors and a second connection electrode which is disposed on the second planarization layer and connects the second electrode and the power line.

The display device can further include a bonding layer disposed between the first connection electrode and the magnetic metal.

The display device can further include an adhesive layer disposed on the plurality of transistors. The plurality of light emitting diodes being disposed on the adhesive layer, each of the plurality of light emitting diodes can further include a first electrode disposed on the first semiconductor layer and a second electrode disposed on the second semiconductor layer. The display device can further include a first planarization layer disposed on the adhesive layer, a first connection electrode which is disposed on the first planarization layer and connects the first electrode and the plurality of transistors, a second planarization layer disposed on the first connection electrode and the first planarization layer and a second connection electrode which is disposed on the second planarization layer and connects the second electrode and the power line. The insulating layer can be in contact with the adhesive layer.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. As such, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A light emitting diode, comprising:
a first semiconductor layer;
an emission layer disposed on the first semiconductor layer;
a second semiconductor layer disposed on the emission layer;
a magnetic metal disposed below the first semiconductor layer; and
an insulating layer disposed to enclose a side surface of the magnetic metal.

2. The light emitting diode according to claim 1, wherein the magnetic metal is in contact with the first semiconductor layer, and
wherein an area of the magnetic metal is smaller than an area of the first semiconductor layer.

3. The light emitting diode according to claim 2, wherein an end of the insulating layer is disposed on a same plane as an end of the first semiconductor layer.

4. The light emitting diode according to claim 2, further comprising:
a first electrode disposed on the first semiconductor layer;
a second electrode disposed on the second semiconductor layer; and
a passivation film disposed to enclose the first semiconductor layer, the emission layer, the second semiconductor layer, a part of the first electrode, and a part of the second electrode,
wherein the passivation film is disposed to be spaced apart from the insulating layer.

5. The light emitting diode according to claim 2, further comprising:
a first electrode disposed on the first semiconductor layer;
a second electrode disposed on the second semiconductor layer; and
a passivation film disposed to enclose the first semiconductor layer, the emission layer, the second semiconductor layer, a part of the first electrode, a part of the second electrode, and a side surface of the insulating layer,
wherein the passivation film is integrally formed with the insulating layer.

6. The light emitting diode according to claim 1, further comprising:
a first electrode disposed among the first semiconductor layer, the magnetic metal, and the insulating layer; and
a second electrode disposed on the second semiconductor layer,
wherein an area of the magnetic metal is smaller than an area of the first electrode.

7. The light emitting diode according to claim 6, wherein an end of the insulating layer is disposed on a same plane as an end of the first electrode.

8. The light emitting diode according to claim 6, further comprising:
a passivation film disposed to enclose side surfaces of the first semiconductor layer, the emission layer, and the second semiconductor layer,
wherein the passivation film is disposed to be spaced apart from the insulating layer.

9. The light emitting diode according to claim 6, further comprising:
a passivation film disposed to enclose side surfaces of the first electrode, the first semiconductor layer, the emission layer, the second semiconductor layer, and the insulating layer,
wherein the passivation film is integrally formed with the insulating layer.

10. The light emitting diode according to claim 1, wherein the magnetic metal includes a paramagnetic material.

11. A substrate for assembling a light emitting diode, the substrate comprising:
a base substrate;
a plurality of assembly electrodes disposed on the base substrate; and
an organic layer disposed on the base substrate and including a plurality of openings configured to expose the plurality of assembly electrodes,
wherein the plurality of assembly electrodes includes a plurality of first assembly electrodes, a plurality of second assembly electrodes, and a plurality of third assembly electrodes having different planar shapes.

12. The substrate for assembling the light emitting diode according to claim 11, wherein the plurality of assembly electrodes includes a paramagnetic material.

13. A display device, comprising:
a substrate in which a plurality of sub pixels is defined;
a power line disposed on the substrate;
a plurality of transistors disposed in each of the plurality of sub pixels on the substrate; and
a plurality of light emitting diodes disposed in the plurality of sub pixels on the power line and the plurality of transistors,
wherein the plurality of light emitting diodes includes a first light emitting diode, a second light emitting diode, and a third light emitting diode which are configured to emit different color lights,
wherein the plurality of light emitting diodes includes a first semiconductor layer, an emission layer disposed on the first semiconductor layer, a second semiconductor layer disposed on the emission layer, a magnetic metal disposed below the first semiconductor layer, and an insulating layer disposed so as to enclose a side surface of the magnetic metal, and
wherein a magnetic metal of the first light emitting diode, a magnetic metal of the second light emitting diode, and a magnetic metal of the third light emitting diode have different planar shapes.

14. The display device according to claim 13, wherein the first light emitting diode, the second light emitting diode, and the third light emitting diode have a same size and a same planar shape and
wherein the magnetic metal of the first light emitting diode, the magnetic metal of the second light emitting diode, and the magnetic metal of the third light emitting diode have a same shape and different positions.

15. The display device according to claim 13, wherein the first light emitting diode, the second light emitting diode, and the third light emitting diode have a same size and a same planar shape and
wherein the first light emitting diode, the second light emitting diode, and the third light emitting diode have different sizes and different shapes.

16. The display device according to claim 13, further comprising:
a first planarization layer disposed on the plurality of transistors and the power line, the plurality of light emitting diodes being disposed on the first planarization layer; and
a second planarization layer disposed on the first planarization layer and disposed to enclose the plurality of light emitting diodes, and
wherein the insulating layer is in contact with the second planarization layer.

17. The display device according to claim 16, wherein each of the plurality of light emitting diodes further includes a first electrode disposed between the first semiconductor layer and the magnetic metal, and a second electrode disposed on the second semiconductor layer, and
wherein the display device further comprises:
a first connection electrode disposed between the plurality of light emitting diodes and the first planarization layer and connecting the first electrode and the plurality of transistors; and
a second connection electrode disposed on the second planarization layer and connecting the second electrode and the power line.

18. The display device according to claim 16, further comprising:
a bonding layer disposed between the first connection electrode and the magnetic metal.

19. The display device according to claim 13, further comprising:
an adhesive layer disposed on the plurality of transistors,
wherein the plurality of light emitting diodes is disposed on the adhesive layer, and
wherein each of the plurality of light emitting diodes further includes a first electrode disposed on the first semiconductor layer and a second electrode disposed on the second semiconductor layer;
a first planarization layer disposed on the adhesive layer;
a first connection electrode disposed on the first planarization layer and connecting the first electrode and the plurality of transistors;
a second planarization layer disposed on the first connection electrode and the first planarization layer; and
a second connection electrode disposed on the second planarization layer and connecting the second electrode and the power line,
wherein the insulating layer is in contact with the adhesive layer.
